(19) United States
(12) Patent Application Publication
(10) Pub. No.: US 2019/0305669 A1
(43) Pub. Date: Oct. 3, 2019

(54) VOLTAGE SOURCE CONVERTER

(71) Applicant: GENERAL ELECTRIC TECHNOLOGY GMBH, BADEN (CH)

(72) Inventors: Robin GUPTA, Stafford, Staffordshire (GB); Rosemary Louise KING, Stafford, Staffordshire (GB); Robert Stephen WHITEHOUSE, Stafford, Staffordshire (GB); Carl David BARKER, Stone, Staffordshire (GB)

(21) Appl. No.: 16/097,330

(22) PCT Filed: Apr. 11, 2017
(86) PCT No.: PCT/EP2017/058663

§ 371 Date: Oct. 29, 2018

(30) Foreign Application Priority Data
Apr. 13, 2016 (GB) 1606322.4

(51) Int. Cl. H02M 1/32; G01R 31/11; G01R 27/18; H02J 3/36

(52) U.S. Cl. CPC H02M 1/32; H02J 3/36; G01R 27/18; G01R 31/11

(57) ABSTRACT

A voltage source converter (VSC) includes AC terminal(s) connected to an AC network, DC terminal(s) connected to a DC network, energy storage device(s) to selectively store and release energy, and switching element(s) connected between the AC and DC terminals. Each switching element and each energy storage device arranged so that each switching element is switchable to selectively switch each energy storage device into circuit with each DC terminal. The VSC further includes a controller to switch each switching element to switch each energy storage device into circuit to use the energy stored to inject test electrical signal(s) into the DC network in response to a fault in the DC network and when the VSC is disconnected from the AC network. The controller also monitors the test electrical response of the DC network to the injection of each test electrical signal to determine characteristic(s) and/or location of the fault.

### BACKGROUND

The invention relates to a voltage source converter, a voltage source converter arrangement, a method of operating a voltage source converter, and a method of operating a voltage source converter arrangement.

In high voltage direct current (HVDC) power transmission networks alternating current (AC) power is typically converted to direct current (DC) power for transmission via overhead lines, under-sea cables and/or underground cables. This conversion removes the need to compensate for the AC capacitive load effects imposed by the power transmission medium, i.e. the transmission line or cable, and reduces the cost per kilometre of the lines and/or cables, and thus becomes cost-effective when power needs to be transmitted over a long distance.

The conversion between DC power and AC power is utilized in power transmission networks where it is necessary to interconnect the DC and AC networks. In any such power transmission network, converters are required at each interface between AC and DC power to effect the required conversion; AC to DC or DC to AC.

### BRIEF SUMMARY

According to a first aspect of the invention, there is provided a voltage source converter comprising: at least one AC terminal for connection to an AC network; at least one DC terminal for connection to a DC network; at least one energy storage device configured to selectively store and release energy; and at least one switching element connected between the AC and DC terminals, the or each switching element and the or each energy storage device arranged in the voltage source converter so that the or each switching element is configured to be switchable to selectively switch the or each energy storage device into circuit with the or each DC terminal,
wherein the voltage source converter further includes a controller configured to operate in a test mode to:
switch the or each switching element to control the switching of the or each energy storage device into circuit with the or each DC terminal so as to use the energy stored in the or each energy storage device to inject one or more test electrical signals into the DC network in response to the presence of a fault in the DC network and when the voltage source converter is disconnected from the AC network; and
monitor the test electrical response of the DC network to the injection of the or each test electrical signal in order to determine at least one characteristic and/or the location of the fault in the DC network.

Following the detection of a fault in the DC network, it is conventional practice to block the voltage source converter and send an open command to an AC circuit interruption device (or AC circuit interruption devices) to isolate the voltage source converter from the AC network. This prevents the AC network from acting as a source of fault current in relation to the fault in the DC network, where such fault current could potentially damage the voltage source converter and the DC network, and thereby de-energises the DC network. After the DC network is de-energised and the de-ionisation time has lapsed, a close command is sent to the AC circuit interruption device to reconnect the voltage source converter to the AC network and re-energise the DC network. Such reconnection is normally intended to resume power transmission as soon as possible in order to minimise power outage time.

However, in the event that the fault is present in the DC network for longer than expected or the fault is permanent (i.e. repair to the DC network is required to remove the permanent fault), premature closure of the AC circuit interruption device leads to the connected AC network experiencing undesirable transients. In addition the continued presence of the fault in the DC network means that it would be necessary to reopen the AC circuit interruption device.

Also, in a DC network comprising a combination of different transmission media, the fault may either be temporary or permanent depending on the transmission medium in which the fault is located. For example, a fault in an overhead transmission line tends to be temporary, while a fault in a transmission cable tends to be permanent. A costly sensing system would be required to accurately ascertain the location of the fault in the DC network in order to confirm whether the fault is a temporary or permanent one. The alternative is to forgo the costly sensing system and close the AC circuit interruption device without checking whether the fault is a temporary or permanent one but there remains the risk that the AC network will unnecessarily experience undesirable transients if the fault is present in the DC network for longer than expected or the fault turns out to be permanent.

Conventionally the AC circuit interruption device may be subjected to multiple reclosures, which is advantageous for dealing with temporary faults. However, multiple reclosures of a mechanical circuit interruption device over a short period of time is limited by the physical design of the device. For example, each reclosure may require the recharging of a spring actuator or the pressurisation of a gas reservoir, which takes time. Thus, a practical high voltage circuit interruption device is disadvantageously limited to a single open-close-open cycle, while requiring a period of several seconds before the next closure can take place. In addition, the operation of the mechanical circuit interruption device leads to wear and tear over time, which gives rise to increased maintenance requirements. Furthermore, the use of multiple reclosures runs the risk of the AC network experiencing undesirable transients as described above.

The configuration of the voltage source converter of the invention permits the determination of at least one characteristic of the fault in the DC network, which in turn can be usefully employed in deciding the next course of action in responding to the occurrence of the fault. By determining the or each characteristic of the fault, it can then be decided whether it would be appropriate to reclose the AC circuit interruption device or to forgo closure of the AC circuit interruption device until repair of the DC network can be done. As a result, the number of closures of the AC circuit interruption device can be minimised, with the preference that the AC circuit interruption device is closed only when the DC network is healthy, i.e. the fault is no longer present in the DC network. This not only ensures that the AC network would not be unnecessarily exposed to the undesirable transients arising from reconnection of the voltage source converter to the AC network when the fault is present in the DC network for longer than expected or the fault is permanent, but also removes the aforementioned drawbacks associated with multiple reclosures of a circuit interruption device.

The configuration of the voltage source converter of the invention also permits the determination of the location of the fault in the DC network. Location of the fault in the DC network allows repair work to be rapidly carried out in order to remove the fault. It will be appreciated that it is not essential to determine whether the fault is a temporary or permanent one in order to be able to identify its location in the DC network.

The configuration of the voltage source converter of the invention also permits the use of the voltage source converter's components to perform the task of determining at least one characteristic or the task of locating the fault in the DC network, and thereby removes the need for separate hardware to carry out the same task, thus providing savings in terms of hardware cost and footprint. Moreover, configuring the voltage source converter's components to be capable of performing both tasks of determining at least one characteristic and determining the location of the fault in the DC network results in further savings in terms of hardware cost and footprint.

The test electrical signal is preferably a DC voltage signal, but may be in the form of other types of electrical signals.

Sensors may be arranged at the or each DC terminal, or elsewhere in the DC network, to monitor the test electrical response of the DC network.

In embodiments of the invention, the monitoring of the test electrical response of the DC network may include the monitoring of the voltage and/or current in the DC network. This may involve monitoring a change, or the absence of any change, in the voltage and/or current in the DC network.

In further embodiments of the invention, the determination of at least one characteristic of the fault in the DC network may include the determination of whether the fault continues to be present in the DC network or is no longer present in the DC network. Such determination can be used to reliably decide whether the AC circuit interruption device can be reclosed to resume power transmission or should remain opened.

In still further embodiments of the invention, the controller may be configured to operate in a further test mode to:
switch the or each switching element to control the switching of the or each energy storage device into circuit with the or each DC terminal so as to use the energy stored in the or each energy storage device to inject one or more further test electrical signals into the DC network in response to the determination that the fault continues to be present in the DC network, and
monitor the test electrical response of the DC network to the injection of the or each further test electrical signal in order to determine whether the fault continues to be present in the DC network or is no longer present in the DC network.

Operating the controller in the further test mode provides greater certainty about the determination that the fault continues to be present in the DC network. The number of further test signals and the time taken to inject the or each further test signal may vary depending on the desired certainty threshold to confirm that the fault continues to be present in the DC network.

The determination of at least one characteristic of the fault in the DC network may include the determination of the type of the fault in the DC network.

In a first example of the determination of the type of the fault in the DC network, when the DC network is arranged in a symmetrical monopole configuration, the test electrical response may include an imbalance between the voltages of the poles of the DC network, which indicates that a pole-to-ground fault is present in the DC network.

In a second example of the determination of the type of the fault in the DC network, when the DC network is arranged in a symmetrical monopole configuration, the test electrical response may include a voltage collapse and an increase in direct current level in the DC network, which indicates that a pole-to-pole fault is present in the DC network.

In a third example of the determination of the type of the fault in the DC network, when the DC network is arranged in an asymmetrical monopole or bipole configuration, the test electrical response may include a voltage collapse and an increase in direct current level in the DC network, which indicates that a fault is present in the DC network.

The determination of the type of fault in the DC network provides information on the fault that can be usefully employed to help decide the next course of action in dealing with the fault.

It will be appreciated that the invention is applicable to the determination of other types of faults in addition to the examples described above.

The controller may be configured to block the voltage source converter in response to the presence of the fault in the DC network and to then de-block the voltage source converter before the or each test electrical signal is injected into the DC network. Under circumstances in which the voltage source converter is blocked following detection of a fault in the DC network, the voltage source converter would have to be de-blocked before the injection of the or each test electrical signal into the DC network can take place.

The controller may be configured to block the voltage source converter in response to the determination that the fault is no longer present in the DC network. Thereafter, a closing command may be sent to the AC circuit interruption device to reconnect the voltage source converter to the AC network.

The monitoring of the test electrical response of the DC network to the injection of the or each test electrical signal in order to determine the location of the fault in the DC network may include the monitoring of at least one reflected signal caused by the presence of the fault in the DC network.

The presence of the fault in the DC network can change the characteristics of the DC network such that one or more additional reflection points are introduced into the DC network in addition to any existing reflection point (if there are any at all). The existence of the or each additional reflection point affects the electrical response of the DC network and hence can be used to help determine the location of the fault.

In such embodiments, the determination of the location of the fault in the DC network may include the determination of a time difference between: an arrival time of a reflected signal caused by the presence of the fault in the DC network; and a corresponding arrival time of the injected test electrical signal, and may include the combination of the time difference with the electrical properties of the DC network to calculate the location of the fault in the DC network. Preferably the time difference is determined using: a first arrival time of a reflected signal caused by the presence of the fault in the DC network; and a first arrival time of the injected test electrical signal.

In embodiments of the invention, the controller may be configured to:
switch the or each switching element to control the switching of the or each energy storage device into circuit with the or each DC terminal so as to use the energy stored in the or each energy storage device to inject one or more reference electrical signals into the DC network when there is no fault in the DC network; and
monitor the electrical response of the DC network to the injection of the or each reference electrical signal in order to establish a reference electrical response of the DC network,
wherein the or each test electrical signal may be configured to match the or each reference electrical signal, and the controller may be further configured to compare the test and reference electrical responses of the DC network in order to determine the location of the fault in the DC network.

The comparison between the test and reference electrical responses of the DC network provides an effective means of determining the location of the fault in the DC network, since the location of the fault can be readily highlighted by the difference(s) between the test and reference electrical responses of the DC network.

It will be appreciated that, although the use of the or each reference electrical signal and the reference electrical response has its advantages, the or each reference electrical signal and the reference electrical response are not essential to the determination of the location of the fault in the DC network.

In a preferred embodiment of the invention, the controller may be configured to switch the or each switching element to control the switching of the or each energy storage device into circuit with the or each DC terminal so as to use the energy stored in the or each energy storage device to inject one or more reference electrical signals into the DC network when there is no fault in the DC network and when the voltage source converter is disconnected from the AC network.

Whilst it is not essential for the voltage source converter to be disconnected from the AC network during the injection of the or each reference electrical signal into the DC network, such disconnection results in the establishment of a more reliable reference electrical response for comparison with the test electrical response.

In embodiments of the invention employing the use of the or each reference electrical signal and the reference electrical response, the or each reference electrical signal may be injected into the DC network with a or a respective reference electrical configuration. For example, the reference electrical configuration may refer to an open-circuit or short-circuit termination of the remote end of a DC transmission medium of the DC network. When the fault in the DC network corresponds to the reference electrical configuration or one of the reference electrical configurations of the DC network, the or each test electrical signal may be configured to match the or each corresponding reference electrical signal.

In further embodiments of the invention employing the use of the or each reference electrical signal and the reference electrical response, the comparison of the test and reference electrical responses of the DC network in order to determine the location of the fault in the DC network may include the identification of one or more reflection points caused by the presence of the fault in the DC network. As mentioned above, the presence of the fault in the DC network may introduce one or more additional reflection points into the DC network, and so identifying the or each additional reflection point would aid in the determination of the location of the fault in the DC network.

In such embodiments, the comparison of the test and reference electrical responses of the DC network in order to determine the location of the fault in the DC network may include: the use of a difference between the test and reference electrical responses to identify one or more reflection points caused by the presence of the fault in the DC network; and/or the use of a discrete wavelet transform to identify one or more reflection points caused by the presence of the fault in the DC network.

In still further embodiments of the invention employing the use of the or each reference electrical signal and the reference electrical response, the or each reference electrical signal may be configured to have a predefined frequency, the or each test electrical signal may be configured to have a predefined frequency, and the controller may be configured to monitor the frequency properties of the test electrical response of the DC network to the injection of the or each test electrical signal in order to determine the location of the fault in the DC network.

The monitoring of the frequency properties of the test electrical response of the DC network in this manner allows the frequency-dependent characteristics of the DC network to be employed in the determination of the location of the fault in the DC network, which can be used to enhance the accuracy of the fault location determination based on the use of the or each reference electrical signal and the reference electrical response.

Optionally the controller may include a neural network configured to monitor the test electrical response of the DC network to the injection of the or each test electrical signal in order to determine the location of the fault in the DC network.

Prior to the occurrence of the fault, the neural network may be trained through injection of a series of electrical signals into the DC network to establish electrical responses corresponding to different fault locations in the DC network. Such training can be performed offline, preferably using simulation models. Such electrical responses may include current magnitude, rate of change of current, frequency information, and so on.

After the neural network is trained, it will be capable of outputting the location of the fault in the DC network based on its analysis of a test electrical response resulting from the injection of the or each test electrical signal into the DC network.

The or each switching element may be configured to be switchable to facilitate the transfer of power between the AC and DC terminals, and the control unit may be configured to selectively switch the or each switching element to perform the converter function of transferring power between the AC and DC terminals.

Such configuration of the or each switching element and the control unit permits the same switching element(s) to be used for the main convertor function of transferring power between the AC and DC terminals and to enable the injection of the or each electrical signal into the DC network.

The voltage source converter may include at least one module, the or each module including a plurality of switching elements and at least one energy storage device, the plurality of switching elements and the or each energy storage device in the or each module arranged to be combinable to selectively provide a voltage source, the plurality of switching elements and the or each energy storage device in the or each module arranged so that the plurality of switching elements are configured to be switchable to selectively switch the or each corresponding energy storage device into circuit with the or each DC terminal.

The provision of at least one such module in the voltage source converter provides a reliable means for injecting the or each electrical signal into the DC network.

A plurality of modules, particularly a plurality of series-connected modules, may define a chain-link converter. The structure of the chain-link converter permits build-up of a combined voltage across the chain-link converter, which is higher than the voltage available from each of its individual modules, via the insertion of the energy storage devices of multiple modules, each providing its own voltage, into the chain-link converter. In this manner switching of the or each switching element in each module causes the chain-link converter to provide a stepped variable voltage source, which permits the generation of a voltage waveform across the chain-link converter using a step-wise approximation.

The or each switching element may include at least one self-commutated switching device. The or each self-commutated switching device may be an insulated gate bipolar transistor, a gate turn-off thyristor, a field effect transistor, an injection-enhanced gate transistor, an integrated gate commutated thyristor or any other self-commutated switching device. The number of switching devices in each switching element may vary depending on the required voltage and current ratings of that switching element.

The or each switching element may further include a passive current check element that is connected in anti-parallel with the or each switching device.

The or each passive current check element may include at least one passive current check device. The or each passive current check device may be any device that is capable of limiting current flow in only one direction, e.g. a diode. The number of passive current check devices in each passive current check element may vary depending on the required voltage and current ratings of that passive current check element.

The or each energy storage device may be, but is not limited to, a capacitor, fuel cell or battery.

In a preferred embodiment of the invention, the voltage source converter may include: first and second DC terminals for connection to the DC network; and at least one converter limb extending between the first and second DC terminals, the or each converter limb including first and second limb portions separated by an or a respective AC terminal, the or each AC terminal for connection to the AC network.

According to a second aspect of the invention, there is provided a voltage source converter arrangement comprising: first and second voltage source converters; and a DC transmission medium to interconnect the DC terminals of the first and second voltage source converters, wherein each voltage source converter is configured in accordance with any of the embodiments of the voltage source converter of the first aspect of the invention.

The features and advantages of the voltage source converter of the first aspect of the invention and its embodiments apply mutatis mutandis to the voltage source converter arrangement of the second aspect of the invention.

There are a myriad of ways in which the first and second voltage source converters can cooperate to enable the determination of at least one characteristic and/or the location of the fault in the DC network, examples of which are described as follows.

In further embodiments of the invention, the controllers of the first and second voltage source converters may be configured to time-synchronise the monitoring of the test electrical responses in order to determine the location of the fault in the DC network.

In still further embodiments of the invention, the controllers of the first and second voltage source converters may be configured so that: the first and second voltage source converters simultaneously inject the respective test electrical signals into the DC network; or one of the first and second voltage source converters injects the or each respective test electrical signal into the DC network followed by the other of the first and second voltage source converters injecting the or each respective test electrical signal into the DC network, and the controllers of the first and second voltage source converters are configured to monitor the test electrical response of the DC network to the simultaneous or sequential injection of the test electrical signals in order to determine the location of the fault in the DC network. In such embodiments, each controller of the first and second voltage source converters may be configured to calculate a respective impedance value based on the test electrical response of the DC network, and either or both of the controllers of the first and second voltage source converters are configured to determine the fault impedance and the location of the fault in the DC network based on the calculated impedance values.

In still further embodiments of the invention, the controllers of the first and second voltage source converters may be configured so that the operation of the controller of one of the first and second voltage source converters in its test mode is assigned priority to operate in its test mode over the operation of the controller of the other of the first and second voltage source converters in its test mode. In such embodiments, the controller of the other of the first and second voltage source converters may be configured to operate in its test mode only after the controller of the other of the first and second voltage source converters has failed to operate in its test mode.

According to a third aspect of the invention, there is provided a method of operating a voltage source converter, the voltage source converter comprising: at least one AC terminal for connection to an AC network; at least one DC terminal for connection to a DC network; at least one energy storage device configured to selectively store and release energy; and at least one switching element connected between the AC and DC terminals, the or each switching element and the or each energy storage device arranged in the voltage source converter so that the or each switching element is configured to be switchable to selectively switch the or each energy storage device into circuit with the or each DC terminal, the method including:
switching the or each switching element to control the switching of the or each energy storage device into circuit with the or each DC terminal so as to use the energy stored in the or each energy storage device to inject one or more test electrical signals into the DC network in response to the presence of a fault in the DC network and when the voltage source converter is disconnected from the AC network; and
monitoring the test electrical response of the DC network to the injection of the or each test electrical signal in order to determine at least one characteristic and/or the location of the fault in the DC network.

The features and advantages of the voltage source converter of the first aspect of the invention and its embodiments apply mutatis mutandis to the method of the third aspect of the invention.

According to a fourth aspect of the invention, there is provided a method of operating a voltage source converter arrangement, the voltage source converter arrangement comprising: first and second voltage source converters; and a DC transmission medium to interconnect the DC terminals of the first and second voltage source converters, wherein the method includes the steps of operating each of the first and second voltage source converters in accordance with the steps of the method of the third aspect of the invention.

The features and advantages of the voltage source converter of the first aspect of the invention, the voltage source converter arrangement of the second aspect of the invention, the method of the third aspect of the invention and their embodiments apply mutatis mutandis to the method of the fourth aspect of the invention.

The voltage source converter arrangement may be, but is not limited to, a HVDC power transmission scheme, a symmetrical monopole arrangement, an asymmetrical monopole arrangement, a bipole arrangement or a DC power grid.

### BRIEF DESCRIPTION OF THE DRAWINGS

An embodiment of the invention will now be described, by way of a non-limiting example, with reference to the accompanying drawings in which:

FIG. 1 schematically shows a voltage source converter arrangement according to an embodiment of the invention;

FIG. 2 schematically shows a voltage source converter that forms part the voltage source converter arrangement of FIG. 1;

FIG. 3 illustrates the occurrence of a fault in the voltage source converter arrangement of FIG. 1; and

FIGS. 4 to 6 illustrate exemplary test electrical responses of a DC transmission link into which an exemplary test electrical signal is injected.

### DETAILED DESCRIPTION

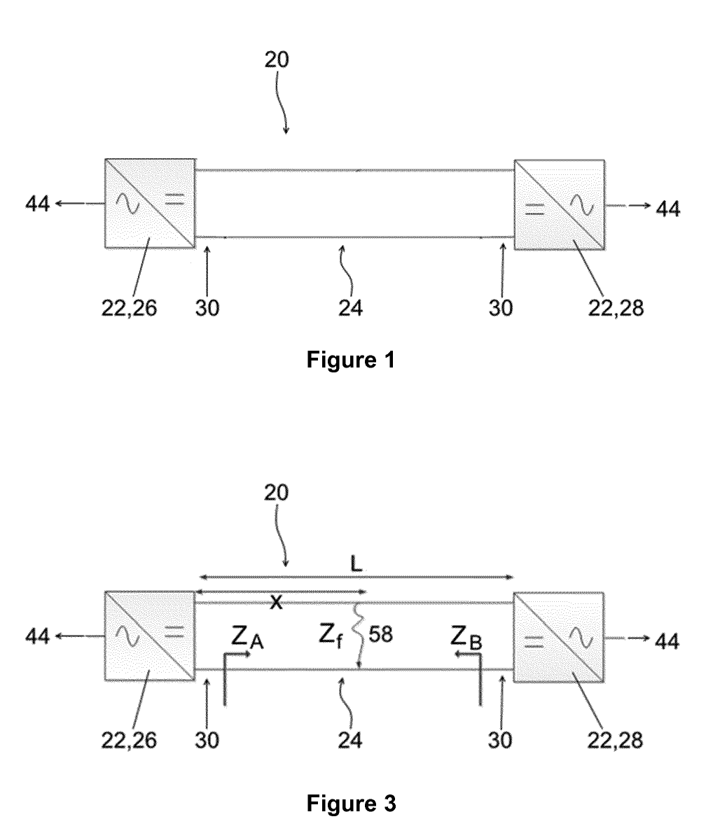

A voltage source converter arrangement according to an embodiment of the invention is shown in FIG. 1, and is designated generally by the reference numeral 20.

The voltage source converter arrangement 20 includes first and second voltage source converters 22 that are interconnected via a DC transmission link 24 (which for example may be in the form of overhead lines, cables or a combination of both). For ease of reference, the reference numerals 26 and 28 will be used to respectively refer to the first and second voltage source converters when there is a need to describe them individually. The DC transmission link 24 extends between two ends 30, which are respectively connected to the first and second voltage source converters 26,28.

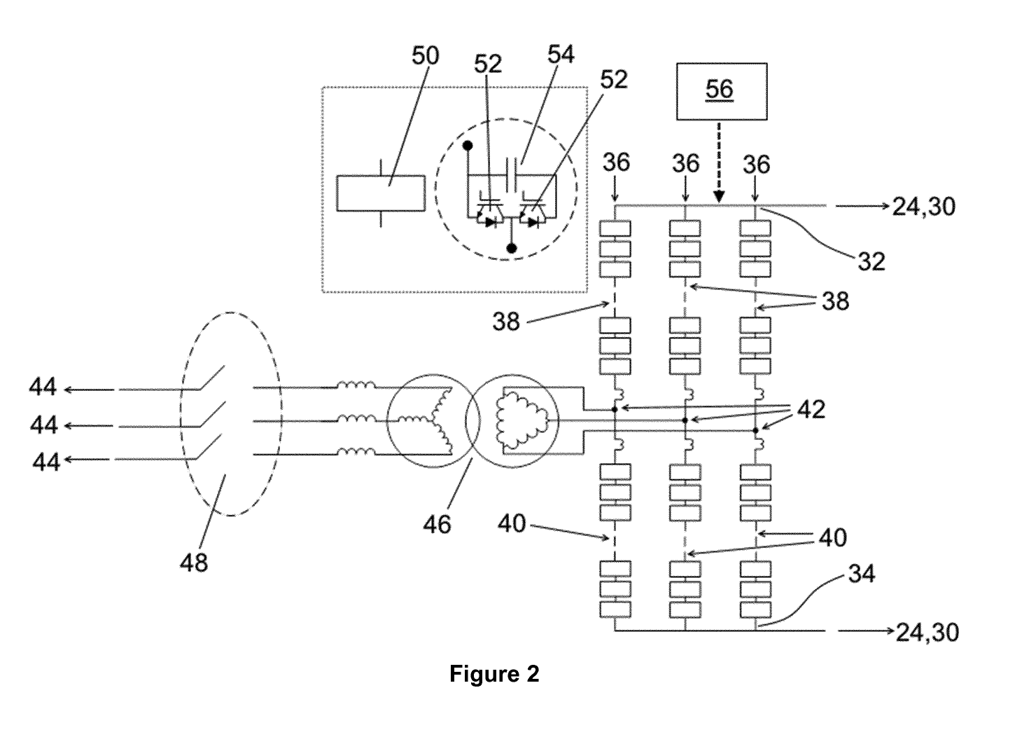

The structure of each voltage source converter 22 is shown schematically in FIG. 2.

Each voltage source converter 22 includes first and second DC terminals 32,34 and a plurality of converter limbs 36. Each converter limb 36 extends between the first and second DC terminals 32,34 and includes first and second limb portions 38,40 separated by a respective AC terminal 42. In each converter limb 36, the first limb portion 38 extends between the first DC terminal 32 and the AC terminal 42, while the second limb portion 40 extends between the second DC terminal 34 and the AC terminal 42.

In use, the first and second DC terminals 32,34 of each voltage source converter 22 are connected to a respective end 30 of the DC transmission link 24, and the AC terminal 42 of each converter limb 36 of each voltage source converter 22 is connected to a respective AC phase of a respective three-phase AC network 44 via a respective star-delta transformer arrangement 46 and a respective AC circuit interruption device in the form of an AC circuit breaker 48.

Each limb portion 38,40 includes a chain-link converter that is defined by a plurality of series-connected modules 50. FIG. 2 shows schematically the structure of each module 50.

Each module 50 includes a pair of switching elements 52 and a capacitor 54 in a full-bridge arrangement. The pair of switching elements 52 are connected in parallel with the capacitor 54 in a half-bridge arrangement to define a 2-quadrant unipolar module that can provide zero or positive voltage and can conduct current in both directions.

Each switching element 52 is in the form of an insulated gate bipolar transistor (IGBT) which is connected in parallel with an anti-parallel diode.

It is envisaged that, in other embodiments of the invention, each IGBT may be replaced by a gate turn-off thyristor, a field effect transistor, an injection-enhanced gate transistor, an integrated gate commutated thyristor or any other self-commutated semiconductor device. It is also envisaged that, in other embodiments of the invention, each diode may be replaced by a plurality of series-connected diodes.

The capacitor 54 of each module 50 is selectively bypassed or inserted into the corresponding chain-link converter by changing the states of the switching elements 52. This selectively directs current through the capacitor 54 or causes current 58 to bypass the capacitor 54, so that the module 50 provides a zero or positive voltage.

The capacitor 54 of the module 50 is bypassed when the switching elements 52 in the module 50 are configured to form a short circuit in the module 50, whereby the short circuit bypasses the capacitor 54. This causes current in the corresponding chain-link converter to pass through the short circuit and bypass the capacitor 54, and so the module 50 provides a zero voltage, i.e. the module 50 is configured in a bypassed mode.

The capacitor 54 of the module 50 is inserted into the corresponding chain-link converter when the switching elements 52 in the module 50 are configured to allow the current in the corresponding chain-link converter to flow into and out of the capacitor 54. The capacitor 54 then charges or discharges its stored energy so as to provide a positive voltage, i.e. the module 50 is configured in a non-bypassed mode.

In this manner the switching elements 52 in each module 50 are switchable to control flow of current through the corresponding capacitor 54.

It is possible to build up a combined voltage across each chain-link converter, which is higher than the voltage available from each of its individual modules 50, via the insertion of the capacitors 54 of multiple modules 50, each providing its own voltage, into each chain-link converter. In this manner switching of the switching elements 52 in each module 50 causes each chain-link converter to provide a stepped variable voltage source, which permits the generation of a voltage waveform across each chain-link converter using a step-wise approximation. Hence, the switching elements 52 in each limb portion 38,40 are switchable to selectively permit and inhibit flow of current through the corresponding capacitor in order to control a voltage across the corresponding limb portion 38,40.

It is envisaged that, in other embodiments of the invention, each module 50 may be replaced by another type of module, which includes a plurality of switching elements and at least one energy storage device, the plurality of switching elements and the or each energy storage device in each such module being arranged to be combinable to selectively provide a voltage source.

It is also envisaged that, in other embodiments of the invention, the capacitor 54 in each module 50,58 may be replaced by another type of energy storage device which is capable of storing and releasing energy to provide a voltage, e.g. a battery or a fuel cell.

Each voltage source converter 22 further includes a respective controller 56 programmed to control the switching of the switching elements 52 of the modules 50 in the limb portions 38,40.

In order to transfer power between the DC transmission link 24 and the respective AC network 44, each controller 56 controls the switching of the switching elements 52 of the modules 50 to switch the respective limb portions 38,40 into and out of circuit between the respective DC and AC terminals 32,34,42 to interconnect the DC transmission link 24 and the respective AC network 44. When a given limb portion 38,40 is switched into circuit between the respective DC and AC terminals 32,34,42, the controller 56 switches the switching elements 52 of the modules 50 of the given limb portion 38,40 to provide a stepped variable voltage source and thereby generate a voltage waveform so as to control the configuration of an AC voltage waveform at the corresponding AC terminal 42 to facilitate the transfer of power between the DC transmission link 24 and the respective AC network 44.

To generate a positive AC voltage component of an AC voltage waveform at the AC terminal 42 of a given converter limb 36, the first limb portion 38 is connected into circuit between the first DC terminal 32 and the corresponding AC terminal 42, and the second limb portion 38 is switched out of circuit between the second DC terminal 34 and the corresponding AC terminal 42.

To generate a negative AC voltage component of an AC voltage waveform at the AC terminal 42 of a given converter limb 36, the first limb portion 38 is switched out of circuit between the first DC terminal 32 and the corresponding AC terminal 42, and the second limb portion 38 is connected into circuit between the second DC terminal 34 and the corresponding AC terminal 42.

The following fault characteristic and location determination using a single voltage source converter 22 is described with reference to the first voltage source converter 26, but applies mutatis mutandis to the second voltage source converter 28.

During the operation of the voltage source converter 22, a fault 58 may appear in the DC transmission link 24, as shown in FIG. 3. The presence of the fault 58 in the DC transmission link may result in a fault current flowing through the diodes of the modules 50 of the voltage source converter 22, which may lead to damage of the voltage source converter 22 and the DC transmission link 24. In the embodiment shown, the half-bridge arrangement of each module 50 prevents each module 50 from blocking the flow of current there through.

Initially, following the detection of the fault 58 in the DC transmission link 24, the voltage source converter 22 is blocked, and an open command is sent to the corresponding AC circuit breaker 48 in order to disconnect the voltage source converter 22 from the AC network 26.

Thereafter, the voltage source converter 22 is de-blocked to allow the controller 56 to operate in a test mode by switching the switching elements 52 of one or more of the modules 50 to control the switching of the corresponding capacitors 54 into circuit with the DC terminals 32,34 so as to use the energy stored in the corresponding capacitors 54 to inject a test electrical signal, in the form of a DC voltage signal, into the DC transmission link 24.

The purpose of injecting the test electrical signal into the DC transmission link 24 is to produce a test electrical response in the DC transmission link 24. The test electrical response is measured using sensors (not shown) arranged at the first and second DC terminals 32,34 to allow the test electrical response to be monitored by the controller 56 (and/or by a user).

The monitoring of the test electrical response of the DC transmission link 24 may include the monitoring of a change, or the absence of any change in, the voltage and current in the DC transmission link 24. This enables the determination of the type of the fault 58 in the DC transmission link 24, and whether the fault 58 continues to be present in the DC transmission link 24 or is no longer present in the DC transmission link 24.

The voltage and current characteristics of the test electrical response is monitored to determine the type of the fault 58 in the DC transmission link 24. If the voltage source converter arrangement 20 is arranged in a symmetrical monopole configuration, the presence of a pole-to-ground fault in the DC transmission link 24 will result in a test electrical response that includes an imbalance between the voltages of the poles of the DC transmission link 24, while the presence of a pole-to-pole fault in the DC transmission link 24 will result in a test electrical response that includes a voltage collapse and an increase in direct current level. If the voltage source converter arrangement 20 is arranged in an asymmetrical monopole configuration, the presence of the fault 58 in the DC transmission link 24 will result in a test electrical response that includes a voltage collapse and an increase in direct current level.

It is envisaged that, in other embodiments of the invention, if the voltage source converter arrangement is arranged in a bipole configuration, the presence of the fault in the DC transmission link will result in a test electrical response that includes a voltage collapse and an increase in direct current level.

If the fault 58 is no longer present in the DC transmission link 24, the test electrical response will be identical to an electrical response of the DC transmission link 24 during its normal operation, and therefore the fault is determined to be a temporary fault. For example, for a voltage source converter arrangement 20 arranged in a symmetrical monopole configuration the absence of the fault will result in a test electrical response including balanced voltages of the poles of the DC transmission link 24, while for a voltage source converter arrangement arranged in a bipole configuration the absence of the fault will result in a test electrical response with normal current levels, i.e. without any overcurrent. At this stage, the voltage source converter 22 is blocked and an open command can be sent to the corresponding AC circuit breaker 48 to reconnect the voltage source converter 22 to the corresponding AC network 44 to resume power transmission.

If the fault 58 continues to be present in the DC transmission link 24, it is determined to be a permanent fault but could instead be a temporary fault that is present in the DC transmission link 24 for longer than expected.

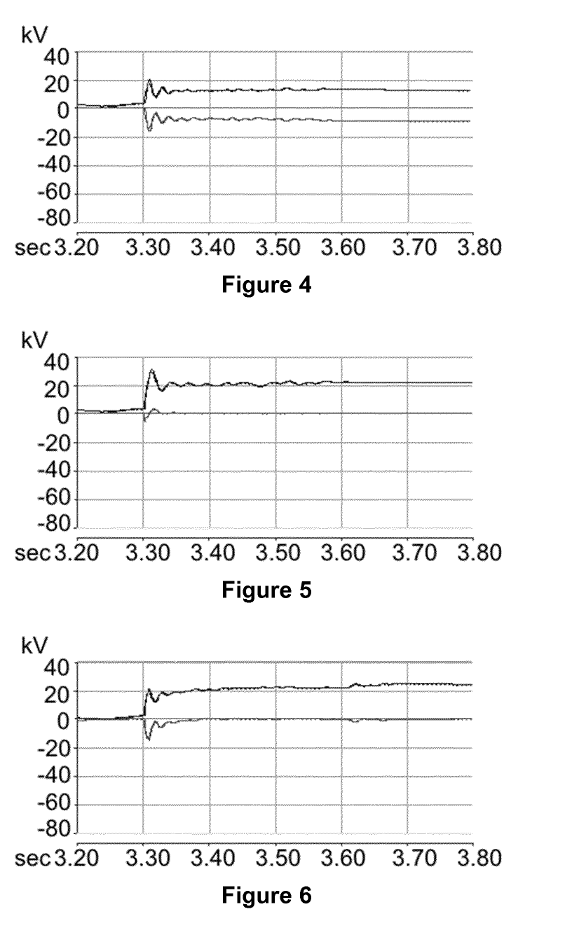

FIGS. 4 to 6 illustrate test electrical responses of the DC transmission link 24 into which a 20 kV DC test electrical signal is injected.

In the case of FIG. 4, the DC transmission link 24 is healthy, i.e. there is no fault in the DC transmission link 24. Accordingly the injection of the test electrical signal into the DC transmission link 24 results in a test electrical response in which the voltages of the poles of the DC transmission link 24 are balanced. A similar test electrical response will arise when the fault 58 is no longer present in the DC transmission link 24.

In the event of a solid pole-to-ground fault, the injection of the test electrical signal into the DC transmission link 24 results in the test electrical response shown in FIG. 5 in which there is an imbalance between the voltages of the poles of the DC transmission link 24 due to a voltage dropping to zero at one of the poles.

In the event of a high impedance pole-to-ground fault with a fault resistance of 200Ω, the injection of the test electrical signal into the DC transmission link 24 results in the test electrical response shown in FIG. 6 in which there is an imbalance between the voltages of the poles of the DC transmission link 24 due to a voltage dropping to zero at one of the poles. The fault resistance of the high impedance pole-to-ground fault means that the corresponding drop in voltage to zero is slower than the drop in voltage to zero for the solid pole-to-ground fault shown in FIG. 5.

Hence it can be seen from FIGS. 4 to 6 that the test electrical response can be used to determine whether a fault is or continues to be present in the DC transmission link 24, and to determine the characteristics of any fault 58 present in the DC transmission link 24.

To obtain greater certainty about the nature of the fault 58, the controller 56 can be optionally operated in a further test mode, in a similar fashion to the test mode, to enable the voltage source converter 22 to inject a plurality of test electrical signals into the DC transmission link 24. The controller 56 then monitors the test electrical response of the DC transmission link 24 to the injection of the further test electrical signals in order to determine whether the fault 58 continues to be present in the DC transmission link 24 or is no longer present in the DC transmission link 24. The number of further test signals and the time taken to inject the further test signals may vary depending on the desired certainty threshold to confirm that the fault 58 continues to be present in the DC transmission link 24.

If the fault 58 is determined to be a permanent fault, repair to the DC transmission link 24 is required to remove the fault 58, and the AC circuit breaker 48 is maintained in its open state to avoid the AC network 44 experiencing undesirable transients. Hence, the ability to determine whether the fault 58 continues to be present in the DC transmission link 24 or is no longer present in the DC transmission link 24 makes it straightforward to decide whether it would be appropriate to reclose the AC circuit breaker 48 or to forgo closure of the AC circuit breaker 48 until repair of the DC transmission link 24 can be done. As a result, the number of closures of the AC circuit breaker 48 can be minimised, with the preference that the AC circuit breaker 48 is closed only when the DC transmission link 24 is healthy, i.e. the fault 58 is no longer present in the DC transmission link 24. This also avoids the earlier-mentioned drawbacks associated with multiple reclosures of the AC circuit breaker 48.

In order to be able to repair the DC transmission link 24 so as to remove the fault 58, it is necessary to identify the location of the fault 58 along the DC transmission link.

It is also possible to locate the fault along the DC transmission link 24 by injecting a test electrical signal and monitoring the test electrical response of the DC transmission link 24.

Firstly, during the commissioning stage (e.g. before the fault 58) of the voltage source converter arrangement 20, the controller 56 is configured to switch the switching elements 52 of one or more of the modules 50 to control the switching of the corresponding capacitors 54 into circuit with the DC terminals 32,34 so as to use the energy stored in the corresponding capacitors 54 to inject a reference electrical signal, in the form of a DC voltage signal, into the DC transmission link 24.

The purpose of injecting the reference electrical signal into the DC transmission link 24 is to produce a reference electrical response in the DC transmission link 24. The reference electrical response is measured using sensors (not shown) arranged at the first and second DC terminals 32,34 to allow the reference electrical response to be monitored by the controller 56 (and/or by a user). The voltage and current of the reference electrical response as measured at the first and second DC terminals 32,34 are recorded and saved by the controller 56.

The nature of waveforms provides details about the characteristics of the DC transmission link 24, akin to a fingerprint. For example, if the DC transmission link 24 includes a transmission portion made from a series connection of overhead line and cable, any joint or transition between the overhead line and cable will result in reflections of any waveform travelling in the DC transmission link 24. The saved reference electrical response can be combined with the length of the DC transmission link 24 to calculate the characteristic values of the DC transmission link 24.

Also, the remote end 30 of the DC transmission link 24, i.e. the end 30 connected to the DC terminals of the second voltage source converter 28, may be terminated in different ways (e.g. an open-circuit or short-circuit termination), with a respective reference electrical signal being injected for each reference electrical configuration.

In order to determine the location of the fault 58 in the DC transmission link 24, the controller 56 is operated in its test mode to enable the voltage source converter 22 to inject a test electrical signal, which matches the earlier injected reference electrical signal, into the DC transmission link 24 to produce a test electrical response. When the fault 58 in the DC transmission link 24 corresponds to an earlier reference electrical configuration of the DC transmission link 24, the test electrical signal is configured to match the corresponding reference electrical signal.

Thereafter, the controller 56 (or a user) compares the test and reference electrical responses of the DC transmission link 24 in order to determine the location of the fault 58 in the DC transmission link 24. Since the fault 58 changes the characteristics of the DC transmission link 24, there will be a difference between the test and reference electrical responses of the DC transmission link 24, and this difference can be used to identify the location of the fault 58 in the DC transmission link 24.

The presence of the fault 58 in the DC transmission link 24 may introduce one or more additional reflection points into the DC transmission link 24, and so identifying the or each additional reflection point would aid in the determination of the location of the fault 58 in the DC transmission link 24. This can be done through the comparison of the test and reference electrical responses of the DC transmission link 24, which may involve: the use of a difference between the test and reference electrical responses to identify one or more reflection points caused by the presence of the fault 58 in the DC transmission link 24; and/or the use of a discrete wavelet transform to identify one or more reflection points caused by the presence of the fault 58 in the DC transmission link 24.

Another method to determine the location of the fault 58 in the DC transmission link 24 is by determining the time difference between: a first arrival time of a reflected signal caused by the presence of the fault 58 in the DC transmission link 24; and a first arrival time of the injected test electrical signal. The distance between the fault 58 and the DC transmission link end 30 connected to the DC terminals 32,34 of the voltage source converter 24 is determined by dividing the characteristic waveform propagation velocity of the DC transmission link 24 (which can be measured during the commissioning stage) with half of the time difference.

The fault location method based on the monitoring of a reflected signal caused by the fault 58 in the DC transmission link 24 is applicable to a DC transmission link including a transmission portion made from a series connection of overhead line and cable. This is because, as mentioned above, any joint or transition between the overhead line and cable will result in reflections of any waveform travelling in the DC transmission link 24.

Optionally the or each reference electrical signal and the or each test electrical signal may be configured to have a predefined frequency, and the controller 56 may be configured to monitor the frequency properties of the test electrical response of the DC transmission link 24 to the injection of the or each test electrical signal in order to determine the location of the fault 58 in the DC transmission link 24. This permits consideration of the frequency-dependent characteristics of the DC transmission link 24 to be employed in the determination of the location of the fault 58 in the DC transmission link 24, which can be designed to enhance the accuracy of the fault location determination.

Optionally the controller 56 may include a neural network configured to monitor the test electrical response of the DC transmission link 24 to the injection of the or each test electrical signal in order to determine the location of the fault 58 in the DC transmission link 24.

Prior to the occurrence of the fault 58, the neural network is trained through injection of a series of electrical signals into the DC transmission link 24 to establish electrical responses corresponding to different fault locations in the DC transmission link 24. Such training can be performed offline, preferably using simulation models. Such electrical responses may include current magnitude, rate of change of current, frequency information, and so on.

After the neural network is trained, it will be capable of outputting the location of the fault 58 in the DC transmission link 24 based on its analysis of a test electrical response resulting from the injection of a test electrical signal into the DC transmission link 24.

It will be appreciated that the use of the or each reference electrical signal and the reference electrical response are not essential to the determination of the location of the fault 58 in the DC transmission link 24.

It will also be appreciated that the use of the or each reference electrical signal and the reference electrical response can be applied to other fault location methods according to other embodiments of the invention.

In addition to the aforementioned ways of determining the fault location in the DC transmission link 24, the first and second voltage source converters 26,28 can be controlled in cooperation to enable the determination of the location of the fault 58 in the DC transmission link 24.

Firstly, the aforementioned fault location method using a single voltage source converter 22 can be carried out individually at each of the first and second voltage source converters 26,28 so that a fault distance from either end 30 of the DC transmission link 24 can be determined. This may be particularly useful if the fault is closer to one end 30 of the DC transmission link 24 than the other end 30, since the reflections due to the fault 58 will be higher and easier to measure when the fault distance is shorter.

Secondly, the controllers 56 of the first and second voltage source converters 26,28 time-synchronises the monitoring of the test electrical responses in order to determine the location of the fault 58 in the DC transmission link 24, preferably using General Radio Packet Service (GPRS).

Thirdly, the controllers 56 of the first and second voltage source converters 26,28 are operated in their test modes such that:
the first and second voltage source converters 26,28 simultaneously inject the respective test electrical signals into the DC transmission link 24; or
one of the first and second voltage source converters 26,28 injects the or each respective test electrical signal into the DC transmission link 24 followed by the other of the first and second voltage source converters 26,28 injecting the or each respective test electrical signal into the DC transmission link 24.

The controllers 56 of the first and second voltage source converters 26,28 are configured to monitor the test electrical response of the DC transmission link 24 to the simultaneous or sequential injection of the test electrical signals in order to determine the location of the fault 58 in the DC transmission link 24.

Thereafter, each controller 56 of the first and second voltage source converters 26,28 calculates a respective impedance value based on the test electrical response of the DC transmission link 24, and either or both of the controllers 56 of the first and second voltage source converters 26,28 are configured to determine the fault impedance and the location of the fault 58 in the DC transmission link 24 based on the calculated impedance values.

For example, each voltage source converter 26,28 injects a test electrical signal of known frequency and voltage V_{A},V_{B} into the DC transmission link 24, and the steady-state current I_{A},I_{B} is monitored by the controller 56 (or a user). The values of voltage V_{A} and the steady-state current I_{A} are used to calculate a respective impedance value Z_{A},Z_{B} with respect to each voltage source converter 26,28. The computation of the fault impedance Z_{f} and fault distance x_{f} is carried out as follows (and can be performed using either controller 56 through communication of a calculated impedance value Z_{A},Z_{B} from one controller 56 to the other):

If z and L are respectively the per unit length impedance and length of the DC transmission link 24 (which can be measured during the commissioning stage), Equations (1) and (2) can be solved to determine the fault impedance Z_{f} and fault distance x_{f} (i.e. the distance from the DC transmission link end 30 connected to the DC terminals 32,34 of the first voltage source converter 26).

$$\begin{matrix}{Z}_{A} = z * x + ( \frac{( z * ( L - x ) * {Z}_{f} )}{( z * ( L - x ) + {Z}_{f} )} ) & ( 1 ) \\ {Z}_{B} = z * ( L - x ) + ( \frac{( z * x * {Z}_{f} )}{( z * x + {Z}_{f} )} ) & ( 2 )\end{matrix}$$

The controllers 56 of the first and second voltage source converters 26,28 may be configured so that the operation of the controller 56 of one of the first and second voltage source converters 26,28 in its test mode is assigned priority to operate in its test mode over the operation of the controller 56 of the other of the first and second voltage source converters 26,28 in its test mode. The controller 56 of the other of the first and second voltage source converters 26,28 may be configured to operate in its test mode only after the controller 56 of the other of the first and second voltage source converters 26,28 has failed to operate in its test mode.

The configuration of the voltage source converter 22 of the invention permits the use of the voltage source converter's components to perform the task of determining at least one characteristic or the task of locating the fault 58 in the DC transmission link 24, and thereby removes the need for separate hardware to carry out the same task, thus providing savings in terms of hardware cost and footprint. Moreover, configuring the voltage source converter's components to be capable of performing both tasks of determining at least one characteristic and determining the location of the fault 58 in the DC transmission link 24 results in further savings in terms of hardware cost and footprint.

It will be appreciated that the aforementioned structure and operation of each voltage source converter 22 also applies mutatis mutandis to a voltage source converter which forms part of a different voltage source converter arrangement and which may not necessarily be connected to another voltage source converter.

It will be understood that the topology of the voltage source converter 22 of the above-described specific embodiment of the invention is merely chosen as a non-limiting example to describe the principle of the invention, and that the invention is applicable to other voltage source converter topologies in which the voltage source converter comprises: at least one AC terminal for connection to an AC network; at least one DC terminal for connection to a DC network; at least one energy storage device configured to selectively store and release energy; and at least one switching element connected between the AC and DC terminals, the or each switching element and the or each energy storage device arranged in the voltage source converter so that the or each switching element is configured to be switchable to selectively switch the or each energy storage device into circuit with the or each DC terminal.

It is envisaged that, in other embodiments of the invention, each voltage source converter may include a single converter limb or any plurality of converter limbs.

What we claim is:

1. A voltage source converter comprising:
at least one AC terminal for connection to an AC network;
at least one DC terminal for connection to a DC network;
at least one energy storage device configured to selectively store and release energy;
at least one switching element connected between the AC and DC terminals, the or each switching element and the or each energy storage device arranged in the voltage source converter so that the or each switching element is configured to be switchable to selectively switch the or each energy storage device into circuit with the or each DC terminal; and
a controller configured to operate in a test mode to:
switch the or each switching element to control the switching of the or each energy storage device into circuit with the or each DC terminal so as to use the energy stored in the or each energy storage device to inject one or more test electrical signals into the DC network in response to the presence of a fault in the DC network and when the voltage source converter is disconnected from the AC network; and
monitor the test electrical response of the DC network to the injection of the or each test electrical signal in order to determine at least one characteristic and/or the location of the fault in the DC network.

2. The voltage source converter according to claim 1, wherein the test electrical signal is a DC voltage signal.

3. The voltage source converter according to claim 1, wherein the monitoring of the test electrical response of the DC network includes the monitoring of the voltage and/or current in the DC network.

4. The voltage source converter according to claim 1, wherein the determination of at least one characteristic of the fault in the DC network includes the determination of whether the fault continues to be present in the DC network or is no longer present in the DC network.

5. The voltage source converter according to claim 1, wherein the controller is configured to operate in a further test mode to:
switch the or each switching element to control the switching of the or each energy storage device into circuit with the or each DC terminal so as to use the energy stored in the or each energy storage device to inject one or more further test electrical signals into the DC network in response to the determination that the fault continues to be present in the DC network, and
monitor the test electrical response of the DC network to the injection of the or each further test electrical signal in order to determine whether the fault continues to be present in the DC network or is no longer present in the DC network.

6. The voltage source converter according to claim 1, wherein the determination of at least one characteristic of the fault in the DC network includes the determination of the type of the fault in the DC network.

7. The voltage source converter according to claim 6, wherein the test electrical response includes any one of a group including:
when the DC network is arranged in a symmetrical monopole configuration, an imbalance between the voltages of the poles of the DC network;
when the DC network is arranged in a symmetrical monopole configuration, a voltage collapse and an increase in direct current level in the DC network;
when the DC network is arranged in an asymmetrical monopole or bipole configuration, a voltage collapse and an increase in direct current level in the DC network.

8. The voltage source converter according to claim 1, wherein the controller is configured to block the voltage source converter in response to the presence of the fault in the DC network and to then de-block the voltage source converter before the or each test electrical signal is injected into the DC network.

9. The voltage source converter according to claim 1, wherein the controller is configured to block the voltage source converter in response to the determination that the fault is no longer present in the DC network.

10. The voltage source converter according to claim 1, wherein the monitoring of the test electrical response of the DC network to the injection of the or each test electrical signal in order to determine the location of the fault in the DC network includes the monitoring of at least one reflected signal caused by the presence of the fault in the DC network.

11. The voltage source converter according to claim 10, wherein the determination of the location of the fault in the DC network includes the determination of a time difference between: an arrival time of a reflected signal caused by the presence of the fault in the DC network; and a corresponding arrival time of the injected test electrical signal, and the combination of the time difference with the electrical properties of the DC network to calculate the location of the fault in the DC network.

12. The voltage source converter according to claim 1, wherein the controller is configured to:
switch the or each switching element to control the switching of the or each energy storage device into circuit with the or each DC terminal so as to use the energy stored in the or each energy storage device to inject one or more reference electrical signals into the DC network when there is no fault in the DC network; and
monitor the electrical response of the DC network to the injection of the or each reference electrical signal in order to establish a reference electrical response of the DC network,
wherein the or each test electrical signal is configured to match the or each reference electrical signal, and the controller is further configured to compare the test and reference electrical responses of the DC network in order to determine the location of the fault in the DC network.

13. The voltage source converter according to claim 12, wherein the controller is configured to switch the or each switching element to control the switching of the or each energy storage device into circuit with the or each DC terminal so as to use the energy stored in the or each energy storage device to inject one or more reference electrical signals into the DC network when there is no fault in the DC network and when the voltage source converter is disconnected from the AC network.

14. The voltage source converter according to claim 12, wherein the or each reference electrical signal is injected into the DC network with a or a respective reference electrical configuration, and wherein, when the fault in the DC network corresponds to the reference electrical configuration or one of the reference electrical configurations of the DC network, the or each test electrical signal is configured to match the or each corresponding reference electrical signal.

15. The voltage source converter according to claim 12 wherein the comparison of the test and reference electrical responses of the DC network in order to determine the location of the fault in the DC network includes the identification of one or more reflection points caused by the presence of the fault in the DC network.

16. The voltage source converter according to claim 15, wherein the comparison of the test and reference electrical responses of the DC network in order to determine the location of the fault in the DC network includes: the use of a difference between the test and reference electrical responses to identify one or more reflection points caused by the presence of the fault in the DC network; and/or the use of a discrete wavelet transform to identify one or more reflection points caused by the presence of the fault in the DC network.

17. The voltage source converter according to claim 12, wherein the or each reference electrical signal is configured to have a predefined frequency, the or each test electrical signal is configured to have a predefined frequency, and the controller is configured to monitor the frequency properties of the test electrical response of the DC network to the injection of the or each test electrical signal in order to determine the location of the fault in the DC network.

18. The voltage source converter according to claim 1, wherein the controller includes a neural network configured to monitor the test electrical response of the DC network to the injection of the or each test electrical signal in order to determine the location of the fault in the DC network.

19. The voltage source converter according to claim 1, wherein the or each switching element is configured to be switchable to facilitate the transfer of power between the AC and DC terminals, and the control unit is configured to selectively switch the or each switching element to perform the converter function of transferring power between the AC and DC terminals.

20. The voltage source converter according to claim 1, including at least one module, the or each module including a plurality of switching elements and at least one energy storage device, the plurality of switching elements and the or each energy storage device in the or each module arranged to be combinable to selectively provide a voltage source, the plurality of switching elements and the or each energy storage device in the or each module arranged so that the plurality of switching elements are configured to be switchable to selectively switch the or each corresponding energy storage device into circuit with the or each DC terminal.

21. A voltage source converter arrangement comprising: first and second voltage source converters; and a DC transmission medium to interconnect the DC terminals of the first and second voltage source converters, wherein each voltage source converter is configured in accordance with claim 1.

22. The voltage source converter arrangement according to claim 21, wherein the controllers of the first and second voltage source converters are configured to time-synchronise the monitoring of the test electrical responses in order to determine the location of the fault in the DC network.

23. The voltage source converter arrangement according to claim 21, wherein the controllers of the first and second voltage source converters are configured so that: the first and second voltage source converters simultaneously inject the respective test electrical signals into the DC network; or one of the first and second voltage source converters injects the or each respective test electrical signal into the DC network followed by the other of the first and second voltage source converters injecting the or each respective test electrical signal into the DC network, and the controllers of the first and second voltage source converters are configured to monitor the test electrical response of the DC network to the simultaneous or sequential injection of the test electrical signals in order to determine the location of the fault in the DC network.

24. The voltage source converter arrangement according to claim 23, wherein each controller of the first and second voltage source converters is configured to calculate a respective impedance value based on the test electrical response of the DC network, and either or both of the controllers of the first and second voltage source converters are configured to determine the fault impedance and the location of the fault in the DC network based on the calculated impedance values.

25. The voltage source converter arrangement according to claim 21, wherein the controllers of the first and second voltage source converters are configured so that the operation of the controller of one of the first and second voltage source converters in its test mode is assigned priority to operate in its test mode over the operation of the controller of the other of the first and second voltage source converters in its test mode.

26. The voltage source converter arrangement according to claim 25, wherein the controller of the other of the first and second voltage source converters is configured to operate in its test mode only after the controller of the other of the first and second voltage source converters has failed to operate in its test mode.

27. A method of operating a voltage source converter, the voltage source converter comprising: at least one AC terminal for connection to an AC network; at least one DC terminal for connection to a DC network; at least one energy storage device configured to selectively store and release energy; and at least one switching element connected between the AC and DC terminals, the or each switching element and the or each energy storage device arranged in the voltage source converter so that the or each switching element is configured to be switchable to selectively switch the or each energy storage device into circuit with the or each DC terminal,
wherein the method includes the steps of:
switching the or each switching element to control the switching of the or each energy storage device into circuit with the or each DC terminal so as to use the energy stored in the or each energy storage device to inject one or more test electrical signals into the DC network in response to the presence of a fault in the DC network and when the voltage source converter is disconnected from the AC network; and
monitoring the test electrical response of the DC network to the injection of the or each test electrical signal in order to determine at least one characteristic and/or the location of the fault in the DC network.

28. A method of operating a voltage source converter arrangement, the voltage source converter arrangement comprising: first and second voltage source converters; and a DC transmission medium to interconnect the DC terminals of the first and second voltage source converters, wherein the method includes the steps of operating each of the first and second voltage source converters in accordance with the steps of the method of claim 27.
